(19) United States
(12) Patent Application Publication
(10) Pub. No.: US 2012/0064698 A1
(43) Pub. Date: Mar. 15, 2012

(54) MULTIPLE SECTION SHOWERHEAD ASSEMBLY

(75) Inventor: DONALD J.K. OLGADO, Palo Alto, CA (US)

(73) Assignee: APPLIED MATERIALS, INC., Santa Clara, CA (US)

(21) Appl. No.: 13/217,078

(22) Filed: Aug. 24, 2011

Related U.S. Application Data
(60) Provisional application No. 61/382,176, filed on Sep. 13, 2010.

(51) Int. Cl. H01L 21/20; C23C 16/455

(52) U.S. Cl. 438/478; 118/715; 257/E21.09

(57) ABSTRACT

Embodiments of the present invention generally provide a method and apparatus that may be utilized for deposition of Group III-nitride films using MOCVD and/or HVPE hardware. In one embodiment, the apparatus is a showerhead assembly made of multiple sections that are isolated from one another and attached to a top plate. Each showerhead section has separate inlets and passages for delivering separate processing gases into a processing volume of a processing chamber without mixing the gases prior to entering the processing volume. In one embodiment, each showerhead section includes a temperature control manifold for flowing a cooling fluid through the respective showerhead section. By providing multiple, isolated showerhead sections, manufacturing complexity and costs are significantly reduced as compared to conventionally manufacturing the entire showerhead from a single block or stack of plates.

### CROSS-REFERENCE TO RELATED APPLICATIONS

This application claims benefit of U.S. provisional patent application Ser. No. 61/382,176, filed Sep. 13, 2010, which is herein incorporated by reference.

### BACKGROUND OF THE INVENTION

1. Field of the Invention

Embodiments of the present invention generally relate to methods and apparatus for chemical vapor deposition (CVD) on a substrate, and, in particular, to a showerhead assembly made up of multiple sections for use in metal organic chemical vapor deposition (MOCVD) and/or hydride vapor phase epitaxy (HYPE).

2. Description of the Related Art

Group III-V films are finding greater importance in the development and fabrication of a variety of semiconductor devices, such as short wavelength light emitting diodes (LED's), laser diodes (LD's), and electronic devices including high power, high frequency, high temperature transistors and integrated circuits. For example, short wavelength (e.g., blue/green to ultraviolet) LED's are fabricated using the Group III-nitride semiconducting material gallium nitride (GaN). It has been observed that short wavelength LED's fabricated using GaN can provide significantly greater efficiencies and longer operating lifetimes than short wavelength LED's fabricated using non-nitride semiconducting materials, such as Group II-VI materials.

One method that has been used for depositing Group III-nitrides, such as GaN, is metal organic chemical vapor deposition (MOCVD). This chemical vapor deposition method is generally performed in a reactor having a temperature controlled environment to assure the stability of a first precursor gas which contains at least one element from Group III, such as gallium (Ga). A second precursor gas, such as ammonia (NH₃), provides the nitrogen needed to form a Group III-nitride. The two precursor gases are injected into a processing zone within the reactor where they mix and move towards a heated substrate in the processing zone. A carrier gas may be used to assist in the transport of the precursor gases towards the substrate. The precursors react at the surface of the heated substrate to form a Group III-nitride layer, such as GaN, on the substrate surface. The quality of the film depends in part upon deposition uniformity which, in turn, depends upon uniform mixing of the precursors across the substrate at a uniform temperature across the substrate.

Multiple substrates may be arranged on a substrate carrier and each substrate may have a diameter ranging from 50 mm to 100 mm or larger. The uniform mixing of precursors over larger substrates and/or more substrates and larger deposition areas is desirable in order to increase yield and throughput. These factors are important since they directly affect the cost to produce an electronic device and, thus, a device manufacturer's competitiveness in the marketplace.

Interaction of the precursor gases with the hot hardware components, which are often found in the processing zone of an LED or LD forming reactor, generally causes the precursor to break-down and deposit on these hot surfaces. Typically, the hot reactor surfaces are formed by radiation from the heat sources used to heat the substrates. The deposition of the precursor materials on the hot surfaces can be especially problematic when it occurs in or on the precursor distribution components, such as the gas distribution device. Deposition on the precursor distribution components affects the flow distribution uniformity over time. Therefore, the gas distribution device may be cooled during deposition processes, which reduces the likelihood that the MOCVD precursors, or HVPE precursors, are heated to a temperature that causes them to break down and affect the performance of the gas distribution device.

As the desired deposition areas increase, the size and complexity of conventional gas distribution devices that are configured to deliver multiple processing gases to the substrates increases, which results in significantly increased manufacturing and transportation costs. For example, in a multiple precursor gas distribution device, a plurality of manifolds and gas passages may be formed in a number of large plates that are then stacked and permanently attached to form the multiple precursor gas distribution device. As the gas distribution devices increase to cover deposition areas of 1 m² and greater with the number of gas distribution passages exceeding 5000 in number, the complexity and cost of manufacturing and transporting these devices dramatically increases. Therefore, there is a need for an improved gas distribution device to provide improved uniformity in the film subsequently deposited over the larger substrates and larger deposition areas while reducing the complexity and manufacturing cost of the gas distribution device.

### SUMMARY OF THE INVENTION

In one embodiment, a showerhead assembly comprises a top plate having a plurality of first gas passages and a plurality of second gas passages formed therethrough, and a plurality of isolated showerhead sections attached to the top plate. Each of the showerhead sections has a first gas manifold formed therein and in fluid communication with one of the first gas passages. Each of the showerhead sections also has a second gas manifold formed therein and in fluid communication with one of the second gas passages.

In another embodiment, a substrate processing apparatus comprises a chamber body, a substrate support, and a showerhead assembly, wherein a processing volume is defined by the chamber body, the substrate support, and the showerhead assembly. The showerhead assembly comprises a top plate having a plurality of first gas passages and a plurality of second gas passages formed therethrough, and a plurality of isolated showerhead sections attached to the top plate. Each of the showerhead sections has a first gas manifold formed therein and in fluid communication with one of the first gas passages and the processing volume, and each of the showerhead sections has a second gas manifold formed therein and in fluid communication with one of the second gas passages and the processing volume. The first and second gas manifolds are isolated from one another within the showerhead section.

In yet another embodiment, a method of processing substrates comprises introducing a first gas into a processing volume of a processing chamber through a plurality of showerhead sections, introducing a second gas into the processing volume of the processing chamber through the plurality of showerhead sections, and cooling each of the showerhead sections by flowing a heat exchanging fluid through a manifold formed in each of the showerhead sections. The first gas is delivered into a first gas manifold within each of the showerhead sections, and the first gas is delivered from the first gas manifold of each of the showerhead sections into the processing volume through a plurality of first gas conduits within each showerhead section. The second gas is delivered into a second gas manifold within each of the showerhead sections, and the second gas is delivered from the second gas manifold of each of the showerhead sections into the processing volume through a plurality of second gas conduits.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic, plan view illustrating one embodiment of a processing system for fabricating compound nitride semiconductor devices according to embodiments described herein.

FIG. 2 is a schematic, cross-sectional view of a metal-organic chemical vapor deposition (MOCVD) chamber for fabricating compound nitride semiconductor devices according to one embodiment.

FIG. 3A is a schematic, bottom view of the showerhead assembly depicted in FIG. 2.

FIG. 3B is a schematic, bottom view of another embodiment of a showerhead assembly.

FIG. 3C is a schematic, bottom view of another embodiment of a showerhead assembly.

FIG. 3D is a schematic, bottom view of another embodiment showerhead assembly.

FIG. 4A is a schematic, bottom view of a first horizontal wall of the showerhead section depicted in FIG. 2.

FIG. 4B is a schematic, bottom view of a second horizontal wall of the showerhead section depicted in FIG. 2.

FIG. 4C is a schematic, bottom view of a third horizontal wall of the showerhead section depicted in FIG. 2.

### DETAILED DESCRIPTION

Embodiments of the present invention generally provide a method and apparatus that may be utilized for deposition of Group III-nitride films using MOCVD and/or HVPE hardware. Generally, the apparatus is a showerhead assembly made of multiple sections that are isolated from one another and attached to a top plate. Each showerhead section has separate inlets and passages for delivering separate processing gases into a processing volume of a processing chamber without mixing the gases prior to entering the processing volume. Each showerhead section preferably includes a temperature control manifold for flowing a cooling fluid through the respective showerhead section. By providing multiple, isolated showerhead sections, manufacturing complexity and costs are significantly reduced as compared to conventionally manufacturing the entire showerhead from a single block or stack of plates.

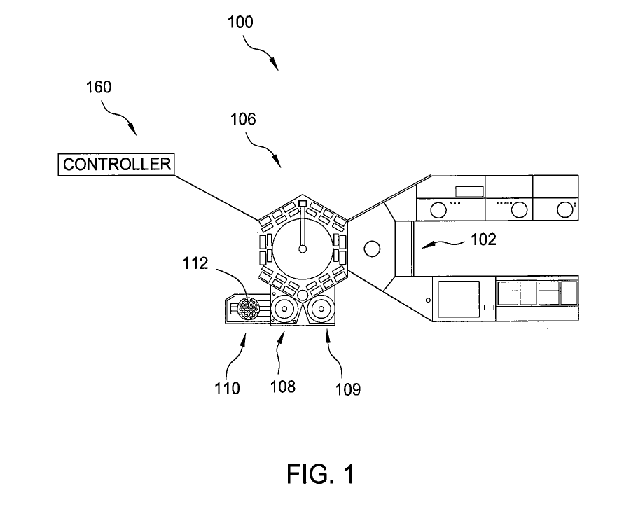

FIG. 1 is a schematic plan view illustrating one embodiment of a processing system 100 that includes one or more MOCVD chambers 102 for fabricating compound nitride semiconductor devices according to embodiments described herein. In one embodiment, the processing system 100 is closed to atmosphere. The processing system 100 comprises a transfer chamber 106, a MOCVD chamber 102 coupled with the transfer chamber 106, a loadlock chamber 108 coupled with the transfer chamber 106, a batch loadlock chamber 109, for storing substrates, coupled with the transfer chamber 106, and a load station 110, for loading substrates, coupled with the loadlock chamber 108. The transfer chamber 106 houses a robot assembly (not shown) operable to pick up and transfer substrates between the loadlock chamber 108, the batch loadlock chamber 109, and the MOCVD chamber 102. Although a single MOCVD chamber 102 is shown, it should be understood that more than one MOCVD chamber 102 or additionally, combinations of one or more MOCVD chambers 102 with one or more Hydride Vapor Phase Epitaxial (HVPE) chambers may also be coupled with the transfer chamber 106. It should also be understood that although a cluster tool is shown, the embodiments described herein may be performed using linear track systems.

In one embodiment, the transfer chamber 106 remains under vacuum during substrate transfer processes to control the amount of contaminants, such as oxygen (O₂) or water (H₂O), to which the substrates are exposed. The transfer chamber vacuum level may be adjusted to match the vacuum level of the MOCVD chamber 102. For example, when transferring substrates from a transfer chamber 106 into the MOCVD chamber 102 (or vice versa), the transfer chamber 106 and the MOCVD chamber 102 may be maintained at the same vacuum level. Then, when transferring substrates from the transfer chamber 106 to the load lock chamber 108 (or vice versa) or the batch load lock chamber 109 (or vice versa), the transfer chamber vacuum level may be adjusted to match the vacuum level of the loadlock chamber 108 or batch load lock chamber 109 even though the vacuum level of the loadlock chamber 108 or batch load lock chamber 109 and the MOCVD chamber 102 may be different. Thus, the vacuum level of the transfer chamber 106 is adjustable. In certain embodiments, substrates are transferred in a high purity inert gas environment, such as, a high purity N₂ environment. In other embodiments, substrates are transferred in a high purity NH₃ or H₂ environment.

In the processing system 100, the robot assembly (not shown) transfers a substrate carrier plate 112 loaded with substrates into the MOCVD chamber 102 to undergo deposition. In one embodiment, the substrate carrier plate 112 may have a diameter ranging from about 200 mm to about 750 mm. The substrate carrier plate 112 may be formed from a variety of materials, including SiC or SiC-coated graphite. As one example, the substrate carrier plate 112 may have a surface area of about 1,000 cm² or more, preferably 2,000 cm² or more, and more preferably 4,000 cm² or more. After some or all deposition steps have been completed, the substrate carrier plate 112 is transferred from the MOCVD chamber 102 back to the loadlock chamber 108 via the transfer robot. The substrate carrier plate 112 may then be transferred to the load station 110. The substrate carrier plate 112 may be stored in either the loadlock chamber 108 or the batch load lock chamber 109 prior to further processing in the MOCVD chamber 102.

A system controller 160 controls activities and operating parameters of the processing system 100. The system controller 160 includes a computer processor and a computer-readable memory coupled to the processor. The processor executes system control software, such as a computer program stored in memory.

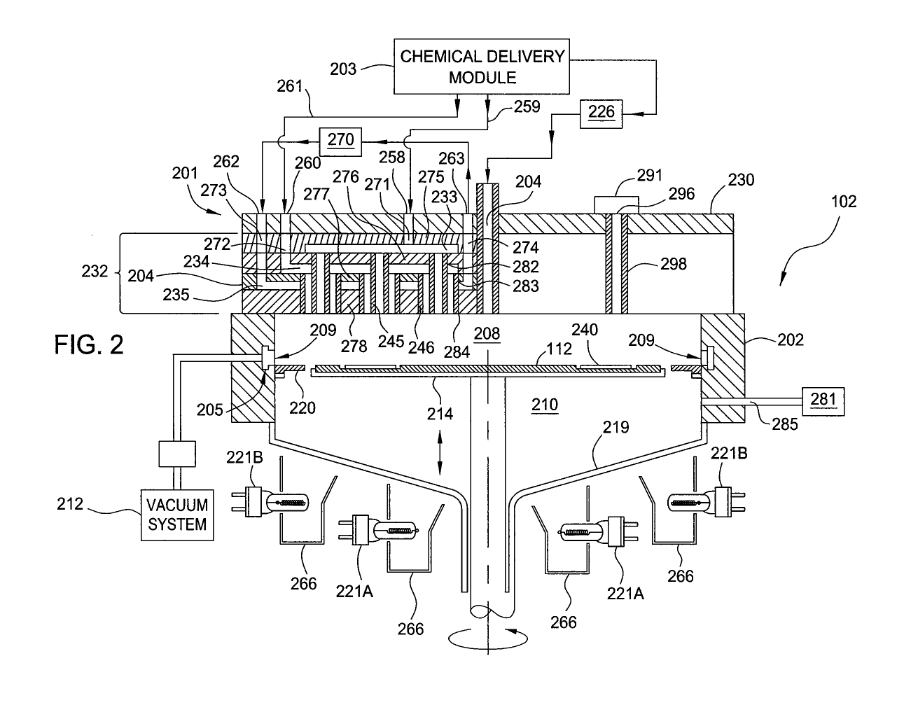

FIG. 2 is a schematic, cross-sectional view of a MOCVD chamber 102 according to one embodiment of the present invention. The MOCVD chamber 102 includes a chamber body 202, a multiple section showerhead assembly 201, and a substrate support 214 defining a processing volume 208. A chemical delivery module 203 is coupled to the showerhead assembly 201 to deliver precursor gases, carrier gases, cleaning gases, and/or purge gases to the processing volume 208. A remote plasma source 226 may be coupled between the chemical delivery module 203 and the showerhead assembly 201. A vacuum system 212 is coupled to the chamber body 202 for evacuating the processing volume 208.

During processing, the substrate carrier plate 112 is positioned on the substrate support 214 within the processing volume 208. An actuator assembly (not shown) is attached to the substrate support 214 and configured to move the substrate support 214 toward and away from the showerhead assembly 201 between processing and loading positions. In addition, the actuator assembly may be configured to rotate the substrate support 214. The distance from the surface of the showerhead assembly 201 that is adjacent the processing volume 208 to the substrate carrier plate 112, during processing, preferably ranges from about 4 mm to about 41 mm. In certain embodiments, the substrate support 214 has a heating element (e.g., a resistive heating element (not shown)) disposed therein and configured to control the temperature of the substrate support 214 and, consequently, the substrate carrier plate 112 positioned on the substrate support as well as substrates 240 positioned on the substrate carrier plate 112.

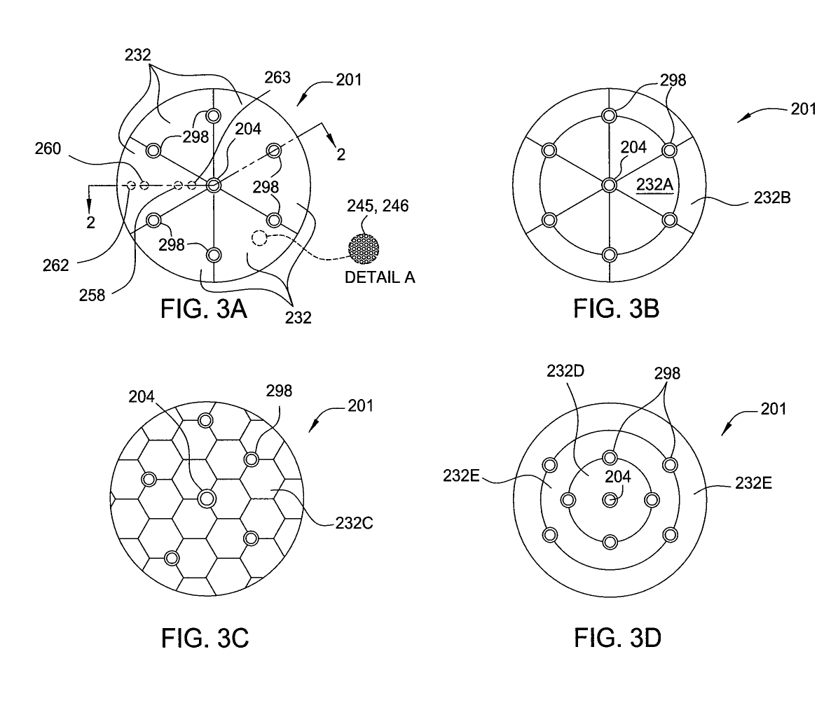

FIG. 3A is a schematic, bottom view of the showerhead assembly 201 depicted in FIG. 2. The cross-sectional view depicted in FIG. 2 is defined by the section line 2-2 shown in FIG. 3A. Referring to FIGS. 2 and 3A, the showerhead assembly 201 includes a top plate 230 coupled to a plurality of showerhead sections 232. The top plate 230 may be a circular aluminum or stainless steel plate having a plurality of apertures formed therethrough for delivering various fluids through the showerhead assembly 201. In one embodiment, each of the showerhead sections 232 are “wedge-shaped” as depicted in FIG. 3A. The wedge-shaped showerhead sections 232 may be assembled together and attached to the top plate 230 to form a circular showerhead assembly 201 as shown in FIG. 3A. Although the embodiment depicted in FIG. 3A includes six wedge-shaped showerhead sections 232, other embodiments include greater or fewer sections 232 without departing from the scope of the invention.

In one embodiment, each showerhead section 232 includes a plurality of plates machined and attached such that a plurality of fluid passages and volumes are formed therein, such as by brazing or welding. In one embodiment, each showerhead section 232 has a first processing gas manifold 233 formed therein and coupled to the chemical delivery module 203 via a gas inlet 258 in the top plate 230 and a gas conduit 259 coupling the gas inlet 258 to the chemical delivery module 203. In one embodiment, the chemical delivery module 203 is configured to deliver a metal organic precursor to the first processing gas manifold 233. In one example, the metal organic precursor comprises a suitable gallium (Ga) precursor (e.g., trimethyl gallium (“TMG”), trimethyl gallium (TEG)), a suitable aluminum precursor (e.g., trimethyl aluminum (“TMA”)), or a suitable indium precursor (e.g., trimethyl indium (“TMI”)). In one embodiment, the first processing gas manifold 233 is bounded on the upper side by a first horizontal wall 275 and on the lower side by a second horizontal wall 276.

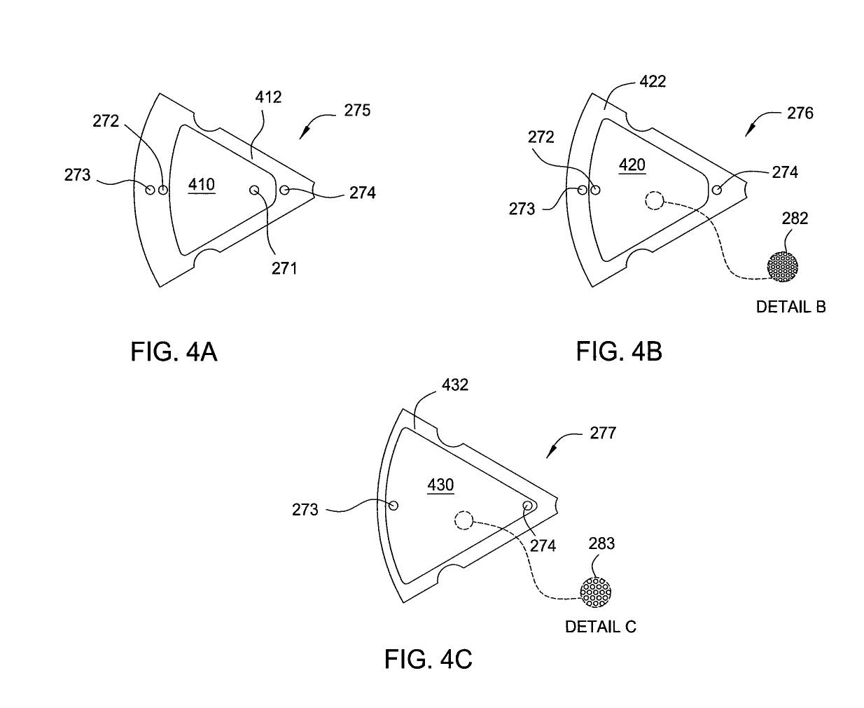

FIG. 4A is a schematic, bottom view of the first horizontal wall 275 of the showerhead section 232 depicted in FIGS. 2 and 3A. Referring to FIGS. 2, 3A, and 4A, the first processing gas manifold 233 may be formed by machining a volume of material from the first horizontal wall 275 to form a well 410 in the bottom surface 412 of the first horizontal wall 275. The first horizontal wall 275 is then attached to the second horizontal wall 276, such as by brazing or welding, so that the periphery of the first processing gas manifold 233 is sealed. The first horizontal wall 275 may be attached to the top plate 230 via screws or other suitable fasteners. The first horizontal wall 275 has a first aperture 271 formed therethrough and positioned such that the gas inlet 258 is fluidly coupled to the first processing gas manifold 233 via the first aperture 271.

Each showerhead section 232 may further include a second processing gas manifold 234 coupled to the chemical delivery module 203 via a gas inlet 260 in the top plate 230 and a gas conduit 261 coupling the gas inlet 260 to the chemical delivery module 203. Each showerhead section 232 includes a gas channel 272 formed therein and positioned to fluidly couple the gas inlet 260 to the second processing gas manifold 234. In one embodiment, the chemical delivery module 203 is configured to deliver a suitable nitrogen containing processing gas, such as ammonia (NH₃) or other MOCVD or HVPE processing gas, to the second processing gas manifold 234. The second processing gas manifold 234 is bounded on the upper side by the second horizontal wall 276 and on the lower side by a third horizontal wall 277 such that processing gases within the first processing gas manifold 233 are isolated from processing gases within the second processing gas manifold 234.

FIG. 4B is a schematic, bottom view of the second horizontal wall 276 of the showerhead section 232 depicted in FIGS. 2 and 3A. Referring to FIGS. 2, 3A, and 4B, the second processing gas manifold 234 may be formed by machining a volume of material from the second horizontal wall 276 to form a well 420 in the bottom surface 422 of the second horizontal wall 276. The second horizontal wall 276 is then attached to the third horizontal wall 277, such as by brazing or welding, so that the second processing gas manifold 234 is sealed about its perimeter. Detail B depicts gas holes 282 through which gas conduits are attached as subsequently described herein.

Each showerhead section 232 may further include a temperature control manifold 235 coupled with a heat exchanging system 270 via a fluid inlet 262 and fluid outlet 263 in the top plate 230. Each showerhead section 232 includes a channel 273 formed therein and positioned to fluidly couple the fluid inlet 262 to the temperature control manifold 235 and a channel 274 formed therein and positioned to fluidly couple the fluid outlet 263 to the temperature control manifold 235. In one embodiment, the temperature control manifold 235 is an open volume formed in the showerhead section 232 that is configured to allow flow of a heat exchanging fluid therethrough. The heat exchanging system 270 is configured to flow the heat exchanging fluid through each showerhead section 232 to help regulate the temperature of the showerhead assembly 201. Suitable heat exchanging fluids include, but are not limited to, water, water-based ethylene glycol mixtures, a perfluoropolyether (e.g., Galden® fluid), oil-based thermal transfer fluids, or similar fluids. In one embodiment, the temperature control manifold 235 is separated from the second processing gas manifold 234 by the third horizontal wall 277 and from the processing volume 208 of the chamber 102 by a fourth horizontal wall 278.

FIG. 4C is a schematic, bottom view of the third horizontal wall 277 of the showerhead section 232 depicted in FIGS. 2 and 3A. Referring to FIGS. 2, 3A, and 4C, the temperature control manifold 235 may be formed by machining a volume of material from the third horizontal wall 277 to form a well 430 in the bottom surface 432 of the third horizontal wall 277. The third horizontal wall 277 is then attached to the fourth horizontal wall 278, such as by brazing or welding, so that the temperature control manifold 235 is sealed about the perimeter. Detail C depicts gas holes 283 through which gas conduits are attached as subsequently described herein.

As previously described, each showerhead section 232 is attached to the top plate 230, such as by suitable fasteners (not shown) engaging blind holes (not shown) formed in the showerhead section 232. In one embodiment, the mating surfaces of the top plate 230 and the showerhead sections 232 are machined so that when they are attached, a metal-to-metal seal is maintained between top plate 230 and the showerhead sections 232 such that fluids entering the showerhead sections 232 are isolated from one another. In other embodiments, other conventional sealing means are used to maintain the fluid isolation, such as o-rings.

In one embodiment, a first precursor, such as a metal organic precursor, is delivered from the first processing gas manifold 233 through the second processing gas manifold 234 and the temperature control manifold 235 into the processing volume 208 of the chamber via a plurality of inner gas conduits 245. The inner gas conduits 245 may be cylindrical tubes located within aligned gas holes 282 disposed through the second horizontal wall 276, gas holes 283 disposed through the third horizontal wall 277, and gas holes 284 disposed through the fourth horizontal wall 278 of each showerhead section 232. In one embodiment, the inner gas conduits 245 are each attached to the second horizontal wall 276 of the showerhead section 232 by suitable means, such as brazing, to maintain isolation between the first processing gas manifold 233 and the second processing gas manifold 234. In one embodiment, the chemical delivery module 203 is configured to supply the first precursor at different flow rates and/or pressures to each of the showerhead sections 232 to provide greater control over deposition processes.

In one embodiment, a second precursor, such as a nitrogen precursor, is delivered from the second processing gas manifold 234 through the temperature control manifold 235 and into the processing volume 208 of the chamber 102 via a plurality of outer gas conduits 246. The outer gas conduits 246 may be cylindrical tubes, each located concentrically about a respective inner gas conduit 245. The outer gas conduits 246 are located within the aligned holes disposed through the third horizontal wall 277 and the fourth horizontal wall 278 of the showerhead section 232. In one embodiment, the outer gas conduits 246 are each attached to the third horizontal wall 277 and fourth horizontal wall 278 of the showerhead section 232 by suitable means, such as by brazing, to maintain isolation between the second processing gas manifold 234 and the temperature control manifold 235. In one embodiment, the chemical delivery module 203 is configured to supply the second precursor at different flow rates and/or pressures to each of the showerhead sections 232 to provide greater control over deposition processes.

It should be noted that only three inner and outer gas conduits 245, 246 are depicted in FIG. 2 for clarity. However, certain embodiments may include about 300 to about 900 inner and outer gas conduits 245, 246 per showerhead section 232 to provide sufficient gas distribution into the process volume 208 for desired deposition onto substrates disposed therein. Detail A in FIG. 3A is an enlarged view of a portion of the bottom surface of the showerhead section 232 showing a number of the inner and outer gas conduits 245, 246.

As previously described, the MOCVD chamber 102 may be used for deposition of group III-nitride films. In one embodiment, the Group III-nitride films are deposited at a temperature exceeding about 550° C. In one embodiment, during processing, a cooling fluid is circulated through the temperature control manifold 235 of each showerhead section 232 in order to cool the showerhead assembly 201, and in particular, to cool the metal organic precursor being delivered through the inner gas conduits 245, which extend through the temperature control manifold 235, to prevent decomposition of the metal organic precursor before it is introduced into the processing volume 208 of the chamber 102. Additionally, it is believed that surrounding the metal organic precursor flowing through each inner gas conduit 245 with a flow of nitrogen-containing gas through the second processing gas manifold 234 and each outer conduit 246, provides additional cooling and thermal insulation from the high processing temperatures within the processing volume 208, in order to prevent decomposition of the metal organic precursor before it is introduced into the processing volume 208. In one embodiment, the heat exchange system 270 is configured to provide flow of the cooling fluid at different rates and/or temperatures to each of the showerhead sections 232 to provide greater control over deposition processes.

In one embodiment, the showerhead assembly 201 includes a central gas conduit 204 extending through a central aperture in the top plate 230. The gas conduit 204 may be a cylindrical tube attached to the top plate 230 by a suitable means, such as brazing. In one embodiment, each of the showerhead sections 232 are formed such that, when all showerhead sections 232 are attached to the top plate 230, an opening is formed to allow passage of the gas conduit 204 through the entire showerhead assembly.

In one embodiment, the chemical supply module 203 supplies cleaning gases to the processing volume 208 of the chamber 102 through the gas conduit 204. In one embodiment, the cleaning gases are excited into a plasma via the remote plasma source 226 prior to being introduced into the processing volume 208. The cleaning gases may include chlorine containing gases, fluorine containing gases, iodine containing gases, bromine containing gases, nitrogen containing gases, and/or other reactive gases.

In one embodiment, the showerhead assembly 201 includes one or more metrology assemblies 291, each attached to a respective metrology port 296. Each metrology port 296 may include a tube 298 that is positioned in an aperture formed through the top plate 230 and extending through the showerhead assembly 201 between indentions formed in adjacent showerhead sections 232. In one embodiment, the tube 298 is attached to the top plate 230 by suitable means, such as brazing. Each metrology assembly 291 is used to monitor the processes performed on the surface of substrates 240 disposed in the processing volume 208 of the chamber 102. In one embodiment, the metrology assembly 291 includes a temperature measurement device, such as an optical pyrometer. In one embodiment, the metrology assembly 291 includes an optical measurement device, such as an optical stress, or substrate bow, measurement device. In one embodiment, a plurality of metrology ports 296 may be positioned concentrically about the central gas conduit 204. In one embodiment, a metrology port 296 may be centrally disposed in place of the central gas conduit 204.

FIGS. 3B-3D are schematic, bottom views of the showerhead assembly 201 according to other embodiments. FIG. 3B depicts the showerhead assembly 201 having a plurality of inner wedge-shaped sections 232A surrounded by an outer ring-shaped section 232B. In one embodiment, the outer ring-shaped section 232B is divided into a plurality of individual sections attached to the top plate 230, as shown in FIG. 3B. In another embodiment, the outer ring-shaped section 232B is a single continuous section. In one embodiment, each of the inner wedge-shaped sections 232A may be supplied with precursors at different flow rates and/or pressures than the outer ring-shaped section 232B to provide greater control over deposition processes. In one embodiment, the temperature and/or flow of the temperature control fluid supplied to each of the wedge-shaped sections 232A may be different than that supplied to the outer ring-shaped section 232B to provide greater control over deposition processes.

In one example, precursor gases may be provided to each of the wedge-shaped sections 232A at a first pressure and flow rate in order to control the pressure and flow of the precursors into a central region of the processing volume 208 of the chamber 102. Simultaneously, precursor gases may be provided to the outer ring-shaped section(s) 232B at a second, higher pressure and flow rate in order to control the pressure and flow of the precursor gases into a peripheral region of the processing volume 208. As a result, finer control over the processing conditions within the processing volume 208 can be achieved. More particularly, finer control over the rate of deposition on substrates, which are typically not positioned in the central region of the processing volume 208, can be achieved by separately controlling the pressure and flow of precursor gases to the central and peripheral regions of the processing volume 208.

In another example, a temperature control fluid may be provided to each of the wedge-shaped sections 232A at a first temperature in order to cool a central portion of the surface of the showerhead assembly 201 facing the processing volume 208 of the chamber 102 at a first desired temperature. Simultaneously, a temperature control fluid may be provided to the outer ring-shaped section(s) 232B at a second temperature in order to cool an outer ring of the surface of the showerhead assembly 201 facing the processing volume 208 of the chamber 102 at a second desired temperature that may be higher or lower than the first desired temperature, depending on the desired processing conditions. As a result, both the temperature of the showerhead assembly 201 and the processing gases entering the processing volume 208 can be controlled by region of the showerhead assembly 201 in an axially symmetric fashion to provide greater control over processing conditions.

Each of the wedge-shaped sections 232A and the outer ring-shaped section(s) 232B has a similar cross-section to that of the showerhead section 232 depicted in FIG. 2. Preferably, the only difference between the showerhead section 232, the wedge-shaped section 232A, and the ring-shaped section(s) 232B is the shape and size of the respective sections. For example, each of the sections 232A and 232B includes a first processing gas manifold 233 having a gas inlet 258 and a plurality of gas conduits 245, a second processing gas manifold 234 having a gas inlet 260 and a plurality of gas conduits 246, and a temperature control manifold 235 having a fluid inlet 262 and fluid outlet 263, as depicted in the showerhead section 232 in FIG. 2. It should also be noted that although no inner and outer gas conduits (245, 246) are depicted in the inner wedge-shaped sections 232A and the outer ring-shaped section 232B for clarity reasons, certain embodiments may include about 100 to about 600 inner and outer gas conduits (245, 246) in each of the sections 232A and 232B and arranged as those depicted in Detail A of FIG. 3A.

FIG. 3C depicts the showerhead assembly 201 having a plurality of hexagonal sections 232C. In one embodiment, each of the hexagonal sections 232C may be supplied with precursors at different flow rates and/or pressures to provide greater control over deposition processes. In one embodiment, the temperature and/or flow of the cooling fluid supplied to the hexagonal sections 232C may be different to provide greater control over deposition processes. In one embodiment, the top plate 230 includes an extended perimeter region (not shown) that mates to the outer hexagonal sections 232C to prevent gaps therebetween.

In one example, precursor gases may be provided to each of the hexagonal sections 232C that are centrally positioned at a first pressure and flow rate in order to control the pressure and flow of the precursors into a central region of the processing volume 208 of the chamber 102. Simultaneously, precursor gases may be provided to the hexagonal sections 232C that are positioned about the periphery of the showerhead assembly 201 at a second, higher pressure and flow rate in order to control the pressure and flow of the precursor gases into a peripheral region of the processing volume 208. As a result, finer control over the rate of deposition on substrates, which are typically not positioned in the central region of the processing volume 208, can be achieved by separately controlling the pressure and flow of precursor gases to the central and peripheral regions of the processing volume 208.

In another example, a temperature control fluid may be provided to each of the hexagonal sections 232C that are centrally positioned at a first temperature in order to cool a central portion of the surface of the showerhead assembly 201 facing the processing volume 208 of the chamber 102 at a first desired temperature. Simultaneously, a temperature control fluid may be provided to the hexagonal sections 232C that are positioned about the periphery of the showerhead assembly 201 at a second temperature in order to cool an outer periphery of the surface of the showerhead assembly 201 facing the processing volume 208 of the chamber 102 at a second desired temperature that may be higher or lower than the first desired temperature, depending on the desired processing conditions. As a result, both the temperature of the showerhead assembly 201 and the processing gases entering the processing volume 208 can be controlled by region of the showerhead assembly 201 in an axially symmetric fashion to provide greater control over processing conditions.

Each of the hexagonal sections 232C has a similar cross-section to that of the showerhead section 232 depicted in FIG. 2. Preferably, the only difference between the showerhead section 232 and the hexagonal section 232C is the shape and size of the respective sections. For example, each of the hexagonal sections 232C includes a first processing gas manifold 233 having a gas inlet 258 and a plurality of gas conduits 245, a second processing gas manifold 234 having a gas inlet 260 and a plurality of gas conduits 246, and a temperature control manifold 235 having a fluid inlet 262 and fluid outlet 263, as depicted in the showerhead section 232 in FIG. 2. It should also be noted that although no inner and outer gas conduits (245, 246) are depicted in the hexagonal sections 232C for clarity reasons, certain embodiments may include about 100 to about 900 inner and outer gas conduits (245, 246) in each of the sections 232C and arranged as those depicted in Detail A of FIG. 3A.

FIG. 3D depicts the showerhead assembly 201 having a circular, central section 232D and a plurality of concentric ring-shaped sections 232E. In one embodiment, the central section 232D and each of the concentric ring-shaped sections 232E may be supplied with precursors at different flow rates and/or pressures to provide greater control over deposition processes. In one embodiment, the temperature and/or flow of the cooling fluid supplied to the central section 232D concentric ring-shaped sections 232E may be different to provide greater control over deposition processes.

In one example, precursor gases may be provided to the central section 232D and each of the ring-shaped sections 232E that are centrally positioned at a first pressure and flow rate in order to control the pressure and flow of the precursors into a central region of the processing volume 208 of the chamber 102. Simultaneously, precursor gases may be provided to the ring-shaped sections 232E that are positioned about the periphery of the showerhead assembly 201 at a second, higher pressure and flow rate in order to control the pressure and flow of the precursor gases into a peripheral region of the processing volume 208. As a result, finer control over the rate of deposition on substrates, which are typically not positioned in the central region of the processing volume 208, can be achieved by separately controlling the pressure and flow of precursor gases to the central and peripheral regions of the processing volume 208.

In another example, a temperature control fluid may be provided to the central section 232D and each of the ring-shaped sections 232E that are centrally positioned at a first temperature in order to cool a central portion of the surface of the showerhead assembly 201 facing the processing volume 208 of the chamber 102 at a first desired temperature. Simultaneously, a temperature control fluid may be provided to the ring-shaped sections 232E that are positioned about the periphery of the showerhead assembly 201 at a second temperature in order to cool an outer periphery of the surface of the showerhead assembly 201 facing the processing volume 208 of the chamber 102 at a second desired temperature that may be higher or lower than the first desired temperature, depending on the desired processing conditions. As a result, both the temperature of the showerhead assembly 201 and the processing gases entering the processing volume 208 can be controlled by region of the showerhead assembly 201 in an axially symmetric fashion to provide greater control over processing conditions.

The central section 232D and each of the ring-shaped sections 232E has a similar cross-section to that of the showerhead section 232 depicted in FIG. 2. Preferably, the only difference between the showerhead section 232, the central section 232D, and the ring-shaped sections 232E is the shape and size of the respective sections. For example, the central section 232D and each of the ring-shaped sections 232E includes a first processing gas manifold 233 having a gas inlet 258 and a plurality of gas conduits 245, a second processing gas manifold 234 having a gas inlet 260 and a plurality of gas conduits 246, and a temperature control manifold 235 having a fluid inlet 262 and fluid outlet 263, as depicted in the showerhead section 232 in FIG. 2. It should also be noted that although no inner and outer gas conduits (245, 246) are depicted in the central section 232D and the ring-shaped sections 232E for clarity reasons, certain embodiments may include about 500 to about 1200 inner and outer gas conduits (245, 246) in each of the sections 232D, 232E and arranged as those depicted in Detail A of FIG. 3A.

Referring back to FIG. 2, a lower dome 219 is disposed below the substrate carrier plate 112 to form a lower volume 210 therebetween. The substrate carrier plate 112 is shown in an elevated, processing position, but may be moved to a lower position where, for example, the substrates 240 may be loaded or unloaded. An exhaust ring 220 may be disposed around the periphery of the substrate carrier plate 112 to help prevent deposition from occurring on the lower dome 219 and also help direct exhaust gases from the chamber 102 to exhaust ports 209. The lower dome 219 may be made of transparent material, such as high-purity quartz, to allow light to pass through for radiant heating of the substrates 240. The radiant heating may be provided by a plurality of inner lamps 221A and outer lamps 221B disposed below the lower dome 219. Reflectors 266 may be used to help control exposure of the chamber 102 to the radiant energy provided by the inner and outer lamps 221A, 221B. Additional rings of lamps (not shown) may also be used for finer temperature control of the substrates 240.

In certain embodiments, purge gas is delivered from a purge gas source 281 through purge gas tubes 285 disposed near the bottom of the chamber body 202. In this configuration, the purge gas enters the lower volume 210 of the chamber 102 and flows upwardly past the substrate carrier plate 112 and exhaust ring 220 into multiple exhaust ports 209, which are disposed around an annular exhaust channel 205.

As noted above, the chemical delivery module 203 supplies chemicals to the MOCVD chamber 102. Reactive gases (e.g., first and second precursor gases), carrier gases, purge gases, and cleaning gases may be supplied from the chemical delivery system through supply lines and into the chamber 102. In one embodiment, the gases are supplied through supply lines and into a gas mixing box where they are mixed together and delivered to the showerhead assembly 201. Generally, supply lines for each of the gases include shut-off valves than can be used to automatically or manually shut-off the flow of the gas into its associated line, and mass flow controllers or other types of controllers that measure the flow of gas or liquid through the supply lines. Supply lines for each of the gases may also include concentration monitors for monitoring precursor concentrations and providing real time feedback. Back pressure regulators may be included to control precursor gas concentrations. Valve switching control may be used for quick and accurate valve switching capability. Moisture sensors in the gas lines measure water levels and can provide feedback to the system software which, in turn, can provide warnings/alerts to operators. The gas lines may also be heated to prevent precursors and cleaning gases from condensing in the supply lines.

In summary embodiments of the present invention include a showerhead assembly made up of multiple showerhead sections that are isolated from one another and attached to a common top plate. Each of the showerhead sections includes separate inlets and passages for delivering separate processing gases into a processing volume of the chamber without mixing the gases prior to entering the processing volume. Each of the showerhead sections also includes a separate temperature control manifold for cooling the respective showerhead section. In comparison to manufacturing the showerhead assembly out of a single block or as a single fabrication, as is the convention, the multiple individual showerhead sections are easier and less costly to manufacture and transport. In addition, the processing gas flows as well as the temperature control fluid can be supplied separately to each of the individual showerhead sections, resulting in greater control over processing conditions as compared to conventional showerheads.

While the foregoing is directed to embodiments of the present invention, other and further embodiments of the invention may be devised without departing from the basic scope thereof, and the scope thereof is determined by the claims that follow. For example, certain embodiments of the showerhead assembly 201 include sections that do not have one or more of the first processing gas manifold 233, the second processing gas manifold 234, and/or the temperature control manifold 235.

1. A showerhead assembly, comprising:
a top plate having a plurality of first gas passages and a plurality of second gas passages formed therethrough; and
a plurality of isolated showerhead sections attached to the top plate, wherein each of the showerhead sections has a first gas manifold formed therein and in fluid communication with one of the first gas passages, wherein each of the showerhead sections has a second gas manifold formed therein and in fluid communication with one of the second gas passages.

2. The assembly of claim 1, wherein each of the first gas passages are isolated from one another and each of the second gas passages are isolated from one another.

3. The assembly of claim 1, wherein the top plate has a plurality of fluid inlets and fluid outlets formed therethrough.

4. The assembly of claim 3, wherein each of the showerhead sections has a fluid manifold formed therein and in fluid communication with one of the fluid inlets and one of the fluid outlets.

5. The assembly of claim 1, wherein the first gas manifold of each showerhead section is located between the top plate and the second gas manifold.

6. The assembly of claim 5, wherein the second gas manifold of each showerhead section is located between the first gas manifold and the fluid manifold.

7. The assembly of claim 1, wherein the first gas manifold of each showerhead section is in fluid communication with an exit side of the showerhead section via a plurality of third gas passages and the second gas manifold of each showerhead section is in fluid communication with the exit side of the showerhead section via a plurality of fourth gas passages.

8. The assembly of claim 7, wherein each of the third and fourth gas passages are configured as concentric tubes.

9. The assembly of claim 1, wherein the showerhead sections have a shape selected from the group consisting of a wedge, a ring, and a hexagon.

10. The assembly of claim 1, further comprising a central gas conduit positioned between adjacent showerhead sections.

11. The assembly of claim 1, further comprising one or more metrology assemblies extending between adjacent showerhead sections.

12. A substrate processing apparatus, comprising:
a chamber body;
a substrate support; and
a showerhead assembly, wherein a processing volume is defined by the chamber body, the substrate support, and the showerhead assembly, and wherein the showerhead assembly comprises:
a top plate having a plurality of first gas passages and a plurality of second gas passages formed therethrough; and
a plurality of isolated showerhead sections attached to the top plate, wherein each of the showerhead sections has a first gas manifold formed therein and in fluid communication with one of the first gas passages and the processing volume, wherein each of the showerhead sections has a second gas manifold formed therein and in fluid communication with one of the second gas passages and the processing volume, and wherein the first and second gas manifolds are isolated from one another within the showerhead section.

13. The apparatus of claim 12, wherein the top plate has a plurality of fluid inlets and fluid outlets formed therethrough, and wherein each of the showerhead sections has a fluid manifold formed therein and in fluid communication with one of the fluid inlets and one of the fluid outlets.

14. The apparatus of claim 12, wherein the showerhead sections have a shape selected from the group consisting of a wedge, a ring, and a hexagon.

15. The apparatus of claim 12, wherein the first gas manifold of each showerhead section is fluidly coupled to the processing volume via a plurality of first gas conduits extending through the second gas manifold.

16. The apparatus of claim 15, wherein the second gas manifold of each showerhead section is fluidly coupled to the processing volume via a plurality of second gas conduits, and wherein each second conduit is concentric about one of the first conduits.

17. The apparatus of claim 12, wherein each first gas passage is coupled to a metal organic gas source, and wherein each second gas passage is coupled to a nitrogen containing gas source.

18. A method of processing substrates, comprising:
introducing a first gas into a processing volume of a processing chamber through a plurality of showerhead sections, wherein the first gas is delivered into a first gas manifold within each of the showerhead sections, and wherein the first gas is delivered from the first gas manifold of each of the showerhead sections into the processing volume through a plurality of first gas conduits within each showerhead section;
introducing a second gas into the processing volume of the processing chamber through the plurality of showerhead sections, wherein the second gas is delivered into a second gas manifold within each of the showerhead sections, wherein the second gas is delivered from the second gas manifold of each of the showerhead sections into the processing volume through a plurality of second gas conduits; and
cooling each of the showerhead sections by flowing a heat exchanging fluid through a manifold formed in each of the showerhead sections.

19. The method of claim 18, wherein the showerhead sections have a shape selected from the group consisting of a wedge, a ring, and a hexagon.

20. The method of claim 18, wherein the first gas is a metal organic precursor and the second gas is a nitrogen containing gas.
